(19) United States
(12) Patent Application Publication
(10) Pub. No.: US 2025/0338510 A1
(43) Pub. Date: Oct. 30, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Yaqin Liu, Wuhan (CN); Wei Liu, Wuhan (CN); Liang Chen, Wuhan (CN); Zhichao Du, Wuhan (CN)

(21) Appl. No.: 18/674,462

(22) Filed: May 24, 2024

Related U.S. Application Data
(63) Continuation of application No. PCT/CN2024/090902, filed on Apr. 30, 2024.

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/33; H01L 2224/08145; H01L 2224/80895; H01L 2224/80896; H01L 2924/1431; H01L 2924/1436

(57) ABSTRACT

Semiconductor devices and fabricating methods are provided. In some implementations, a disclosed semiconductor device comprises a memory array structure and a peripheral circuit structure connected with the memory array structure. The memory array structure comprises a transistor layer comprising a plurality of arrays of vertical transistors, a storage layer comprising a plurality of arrays of capacitors coupled with the vertical transistors, a plurality of bit lines coupled with the vertical transistors, and a first interconnection layer comprising a first interconnection structure connected with the plurality of bit lines, and a second interconnection structure disconnected with the plurality of bit lines and connected to a common electrical node. The peripheral circuit structure comprises a second interconnection layer comprising a third interconnection structure connected with the first interconnection structure, and a sense amplifier circuit connected with the third interconnection structure.

### CROSS-REFERENCE TO RELATED APPLICATIONS

This application is a continuation of International Application No. PCT/CN2024/090902, filed on Apr. 30, 2024, which is hereby incorporated by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a semiconductor device, comprising: a memory array structure comprising: a transistor layer comprising a plurality of arrays of vertical transistors, a storage layer comprising a plurality of arrays of capacitors coupled with the vertical transistors, a plurality of bit lines coupled with the vertical transistors, and a first interconnection layer comprising a first interconnection structure connected with the plurality of bit lines, and a second interconnection structure disconnected with the plurality of bit lines and connected to a common electrical node; and a peripheral circuit structure connected with the memory array structure, and comprising: a second interconnection layer comprising a third interconnection structure connected with the first interconnection structure, and a sense amplifier circuit connected with the third interconnection structure.

In some implementations, the second interconnection layer further comprises: a fourth interconnection structure disconnected with the sense amplifier circuit and the first interconnection structure, and connected to the common electrical node.

In some implementations, the first interconnection structure is connected between bit lines of adjacent arrays of vertical transistors.

In some implementations, the first interconnection structure comprises: a plurality of first conductive lines arranged along a first lateral direction, each first conductive line extends along a second lateral direction and is coupled with a corresponding one of the bit lines through a bit line contact structure.

In some implementations, adjacent first conductive lines have different first lengths along the second lateral direction.

In some implementations, the second interconnection structure comprises: a plurality of second conductive lines arranged along the first lateral direction, and connected to a common conductive line extending along the first lateral direction; wherein each second conductive line extends along the second lateral direction and is aligned with a corresponding one of the first conductive lines.

In some implementations, adjacent second conductive lines have different second lengths along the second lateral direction.

In some implementations, the first interconnection layer comprises at least two layers of conductive lines; and the first interconnection structure and the second interconnection structure are portions of the at least two layers of conductive lines.

In some implementations, the second interconnection layer comprises at least two layers of conductive lines; and the third interconnection structure and the fourth interconnection structure are portions of the at least two layers of conductive lines.

In some implementations, the memory array structure further comprises: first bit line contact structures located at a first side of a corresponding array of vertical transistors, and in contact with odd bit lines of the corresponding array of vertical transistors; and second bit line contact structures located at a second side of the corresponding array of vertical transistors opposite to the first side, and in contact with even bit lines of the corresponding array of vertical transistors.

Another aspect of the present disclosure provides a semiconductor device, comprising: vertical transistors; bit lines coupled with the vertical transistors; a first interconnection structure comprising: first conductive lines arranged along a first lateral direction, each first conductive line extending along a second lateral direction and being connected with a corresponding one of the bit lines, and second conductive lines arranged along a first lateral direction, each second conductive line extending along the second lateral direction and being connected to a common electrical node and disconnected with the bit lines; and a sense amplifier circuit connected with plurality of bit lines through the first conductive lines.

In some implementations, the semiconductor device further comprises a second interconnection structure comprising: third conductive lines connected between the first conductive lines and the sense amplifier circuit; and fourth conductive lines connected to the common electrical node, and disconnected with the sense amplifier circuit and the first interconnection structure.

In some implementations, the first interconnection structure is connected between bit lines of adjacent arrays of vertical transistors.

In some implementations, each first conductive line is aligned with a corresponding one of the second conductive lines along the second lateral direction.

In some implementations, adjacent first conductive lines have different first lengths along the second lateral direction.

In some implementations, the second conductive lines are connected to a common conductive line extending along the first lateral direction.

In some implementations, adjacent second conductive lines have different second lengths along the second lateral direction.

In some implementations, the first conductive lines and the second conducive lines are distributed in at least two conductive wiring layers along a vertical direction.

In some implementations, the third conductive lines and the fourth conducive lines are distributed in at least two conductive wiring layers along a vertical direction.

In some implementations, the semiconductor device further comprises first bit line contact structures located at a first side of a corresponding array of vertical transistors, and in contact with odd bit lines of the corresponding array of vertical transistors; and second bit line contact structures located at a second side of the corresponding array of vertical transistors opposite to the first side, and in contact with even bit lines of the corresponding array of vertical transistors.

Another aspect of the present disclosure provides a method for forming a semiconductor device, comprising: forming a memory array structure comprising: forming a transistor layer comprising a plurality of arrays of vertical transistors, forming a storage layer comprising a plurality of arrays of capacitors coupled with the vertical transistors, forming a plurality of bit lines coupled with the vertical transistors, and forming a first interconnection layer comprising a first interconnection structure connected with the plurality of bit lines, and a second interconnection structure disconnected with the plurality of bit lines and coupled with a first common electric node; forming a peripheral circuit structure comprising: forming a second interconnection layer comprising a third interconnection structure, and forming a sense amplifier circuit connected with the third interconnection structure; and connecting the peripheral circuit structure with the memory array structure, such that the third interconnection structure is coupled with the first interconnection structure.

In some implementations, forming the second interconnection layer further comprises forming a fourth interconnection structure disconnected with the sense amplifier circuit and the first interconnection structure, and connected to a second common electrical node; and connecting the peripheral circuit structure with the memory array structure comprises connecting the first common electric node to the second common electrical node.

In some implementations, forming the first interconnection layer comprises: connecting the first interconnection structure between bit lines of adjacent arrays of vertical transistors.

In some implementations, forming the first interconnection layer comprises: forming a plurality of first conductive lines arranged along a first lateral direction, each first conductive line extends along a second lateral direction and is coupled with a corresponding one of the bit lines through a bit line contact structure.

In some implementations, forming the plurality of first conductive lines comprises forming adjacent first conductive lines having different first lengths along the second lateral direction.

In some implementations, forming the second interconnection structure comprises: forming a plurality of second conductive lines arranged along the first lateral direction and connected to a common conductive line extending along the first lateral direction; wherein each second conductive line extends along the second lateral direction and is aligned with a corresponding one of the first conductive lines.

In some implementations, forming the plurality of second conductive lines comprises forming adjacent second conductive lines having different second lengths along the second lateral direction.

In some implementations, forming the first interconnection layer comprises: forming at least two layers of conductive lines, wherein the first interconnection structure and the second interconnection structure are portions of the at least two layers of conductive lines.

In some implementations, forming the second interconnection layer comprises: forming at least two layers of conductive lines, wherein the third interconnection structure and the fourth interconnection structure are portions of the at least two layers of conductive lines.

In some implementations, forming the memory array structure further comprises: forming first bit line contact structures located at a first side of a corresponding array of vertical transistors, and in contact with odd bit lines of the corresponding array of vertical transistors; and forming second bit line contact structures located at a second side of the corresponding array of vertical transistors opposite to the first side, and in contact with even bit lines of the corresponding array of vertical transistors.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor, according to some implementations of the present disclosure.

FIG. 2 illustrates a schematic layout diagram of a memory chip, according to some implementations of the present disclosure.

FIG. 3A illustrates a schematic top view of a portion of a memory bank, according to some implementations of the present disclosure.

FIG. 3B illustrates a schematic top view of a portion of a memory bank, according to some implementations of the present disclosure.

FIG. 4 illustrates a schematic top view of a portion of a memory bank, according to some implementations of the present disclosure.

FIG. 5 illustrates a schematic side cross-sectional view of a portion of a memory bank, according to some implementations of the present disclosure.

FIG. 6 illustrates a schematic side cross-sectional view of a portion of a memory bank, according to some implementations of the present disclosure.

FIG. 7 illustrates a schematic side cross-sectional view of a portion of a memory bank, according to some implementations of the present disclosure.

FIG. 8 illustrates a schematic top view of a portion of a memory bank, according to some implementations of the present disclosure.

FIG. 9 illustrates a block diagram of a system having a memory device, according to some implementations of the present disclosure.

FIG. 10 illustrates a flowchart of a fabricating method for forming a semiconductor device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. A sense amplifier (SA) circuit can be connected between two bit lines (BLs), where one BL is connected to the capacitor storing the data to be read, while the other BL serves as a reference voltage. The function of the SA circuit is to amplify the voltages on these two BLs, thus allowing for the correct data to be read. Sense margin refers to the voltage difference between the two BLs. A larger voltage difference increases the probability of the SA circuit functioning correctly. If the voltage difference between the two BLs is relatively small, there's a risk that the SA circuit may cause data flipping during operations, resulting in incorrect data readout. Therefore, it's crucial to ensure an adequate sense margin to maintain the reliability of data reading.

With the iterative advancement of DRAM products, the reduction in capacitance of the capacitors due to fabricating processes factors leads to a decrease in sense margin. In some 4F2 DRAM architectures, the SA circuits and word line driver (WLD) circuits are positioned directly beneath the memory arrays to enhance area efficiency. Additionally, to improve BL pick-up window, some 4F2 DRAM architectures use BL interconnection structures to pick up the odd and even BLs at opposite sides of the memory arrays, respectively. Compared to traditional 6F2 DRAM architectures, the total coupling capacitance of capacitors and BLs is much smaller because of the BLs and word lines (WLs) being led out at two ends of the transistor layer, and the introduction of coupling capacitance between BLs. These factors combined result in an insufficient sense margin. Therefore, effectively enhancing sense margin is an urgent problem in designing DRAM architectures.

To address one or more of the aforementioned issues, the present disclosure introduces DRAM architectures in which portions of the interconnect layers used for connecting the BLs and the circuits are used as metal shielding structures. Specifically, the odd and even BLs are routed to opposite sides of the memory arrays to connect to the SA circuits through metal interconnects located at the bottom of the memory array. The metal interconnect layer for BLs pick-up has additional metal lines at each side that can be connected to a fixed voltage potential to act as shielding lines. The shielding lines can effectively increase the total coupling capacitance of the BLs, thereby optimizing the sense margin to ensure reliable data read operations. The shielding lines can be formed in the same front-end-of-line (FEOL) process, or a back-end-of-line (BOEL) process of forming the BL interconnect structures. The disclosed solution can significantly reduce the BL-BL parasitic capacitance, thereby lowering the capacitance requirements for the capacitors, enhancing sense margin, reducing the difficulty of capacitor fabrication, improving the performance and reliability of the DRAM, and opening up pathways for further shrinkage with the continuous scaling development of DRAM.

Consistent with the scope of the present disclosure, according to some implementations of the present disclosure, the memory cell array has vertical transistors each comprising a semiconductor layer extending in a vertical direction, and a gate structure beside the semiconductor layer or surrounded by the semiconductor layer. In some implementations, the WLs and BLs connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased.

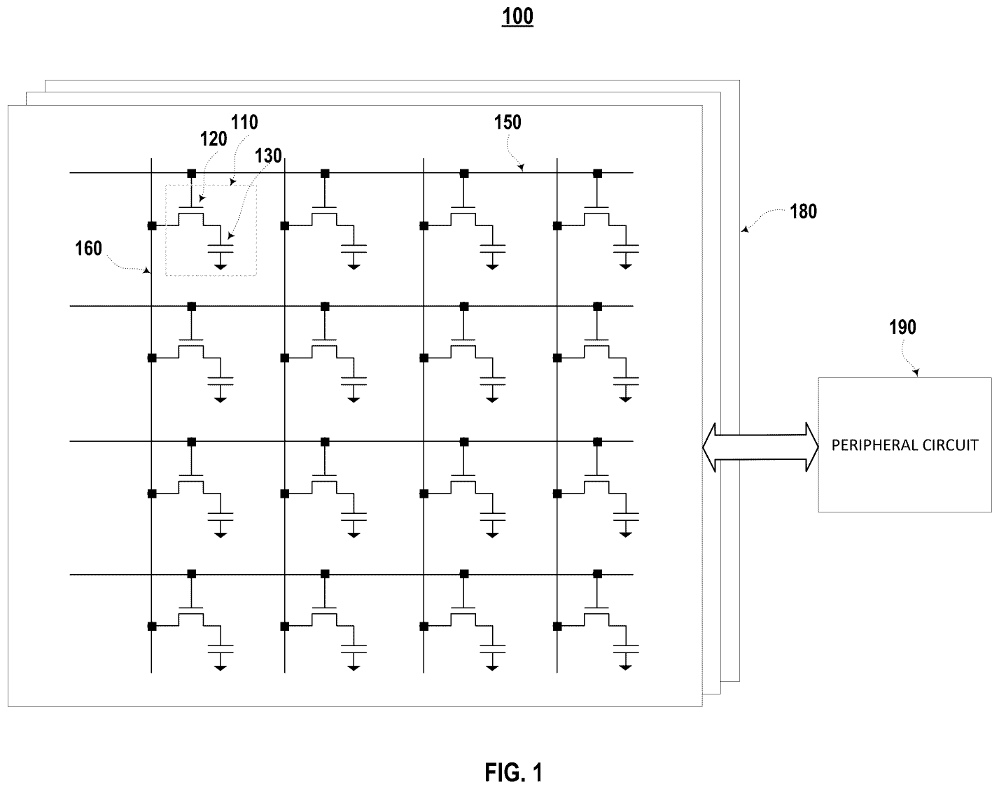

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) memory cell array 180 having rows and columns. Memory device 100 can include word lines 150 coupling the memory cell array 180 to peripheral circuits 190 for controlling the switch of vertical transistors 120 in memory cells 110 located in a row, as well as bit lines 160 coupling the memory cell array 180 to peripheral circuits 190 for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground. Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity.

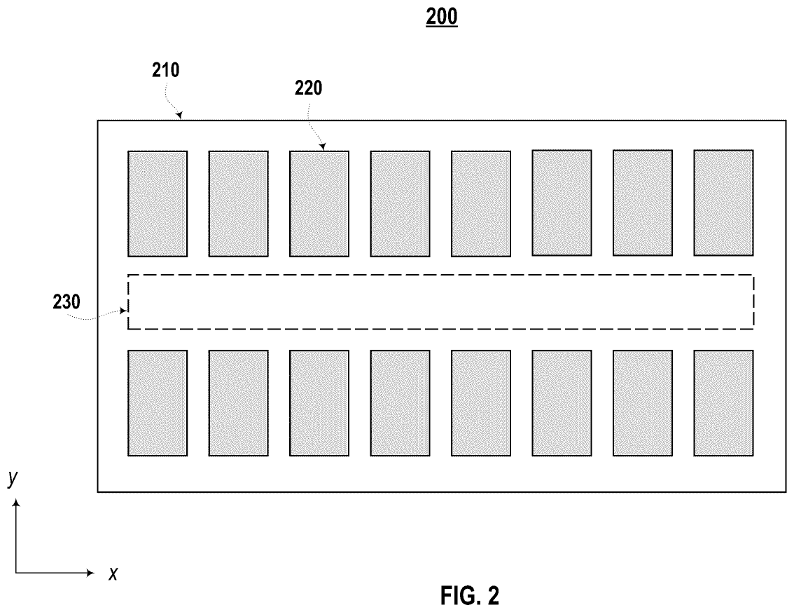

FIG. 2 illustrates a schematic layout diagram of a memory chip 200, according to some implementations of the present disclosure. In some implementations, memory chip 200 can include a die 210 with a square or rectangular shape. Die 210 can include a plurality (e.g., 16 or any other suitable number) of memory banks 220. Each memory bank 220 can include a plurality of memory cell arrays (e.g., memory cell arrays 180 described above in connection with FIG. 1) that are arranged in rows along the x-direction and/or columns in the y-direction. A spacer region 230 can be located between adjacent rows of memory banks 220.

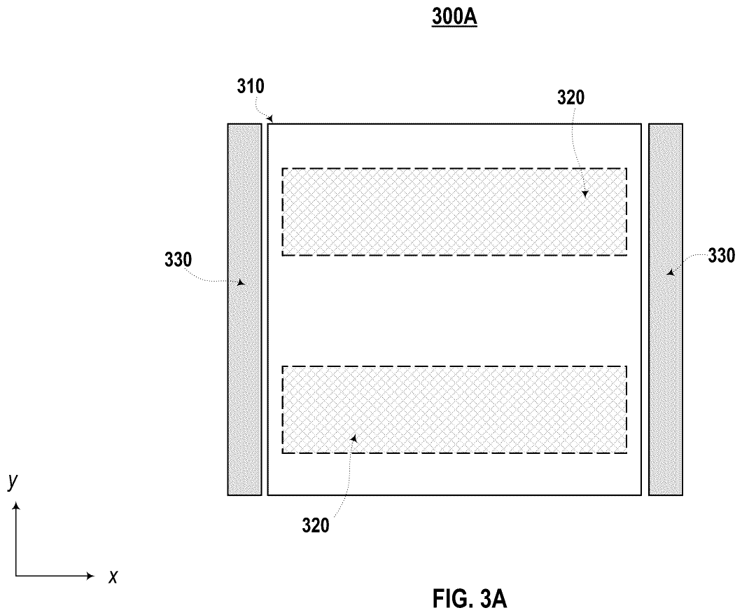

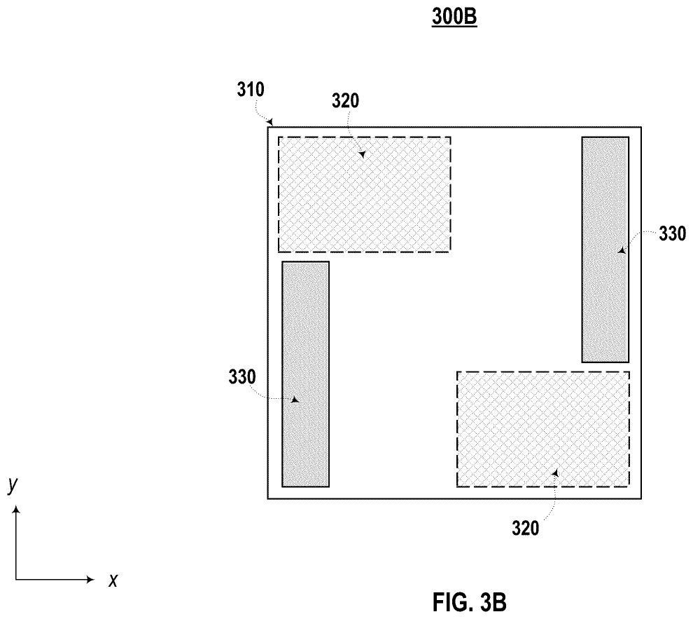

FIG. 3A illustrates a schematic layout diagram of a portion of a memory bank 300A, according to some implementations of the present disclosure. As shown in FIG. 3A, WLD circuits 330 can be located on both sides of memory cell array 310, while SA circuits 320 can be located overlapping with the memory cell array 310 along a vertical direction. That is, a projection of the SA circuits 320 on a lateral plane is located within a projection of the memory cell array 310 on the lateral plane. It is noted that, the memory cell array 310 can be formed on a first wafer, while the SA circuits 320 and the WLD circuits 330 can be portions of the periphery circuits that are formed on a second wafer. The memory bank 300A can be formed by bonding the first wafer comprising the memory cell array 310 with the second wafer comprising the SA circuits 320 and the WLD circuits 330. Therefore, the SA circuits 320 and the WLD circuits 330 are not located on the same lateral plane on which the memory cell array 310 is located. FIG. 3A merely shows a top view of the portion of a memory bank 300A.

FIG. 3B illustrates a schematic layout diagram of a portion of a memory bank 300B, according to some implementations of the present disclosure. As shown in FIG. 3B, WLD circuits 330 and SA circuits 320 can be located overlapping with the memory cell array 310 along a vertical direction. That is, a projection of the WLD circuits 330 and SA circuits 320 on a lateral plane is located within a projection of the memory cell array 310 on the lateral plane. In some implementations, the WLD circuits 330 can be located overlapping with two corners along a first diagonal of the memory cell array 310, and the SA circuits 320 can be located overlapping with two corners along a second diagonal of the memory cell array 310. It is noted that, the memory cell array 310 can be formed on a first wafer, while the SA circuits 320 and the WLD circuits 330 can be portions of the periphery circuits that are formed on a second wafer. The memory bank 300A can be formed by bonding the first wafer comprising the memory cell array 310 with the second wafer comprising the SA circuits 320 and the WLD circuits 330. Therefore, the SA circuits 320 and the WLD circuits 330 are not located on the same lateral plane on which the memory cell array 310 is located. FIG. 3A merely shows a top view of the portion of a memory bank 300A.

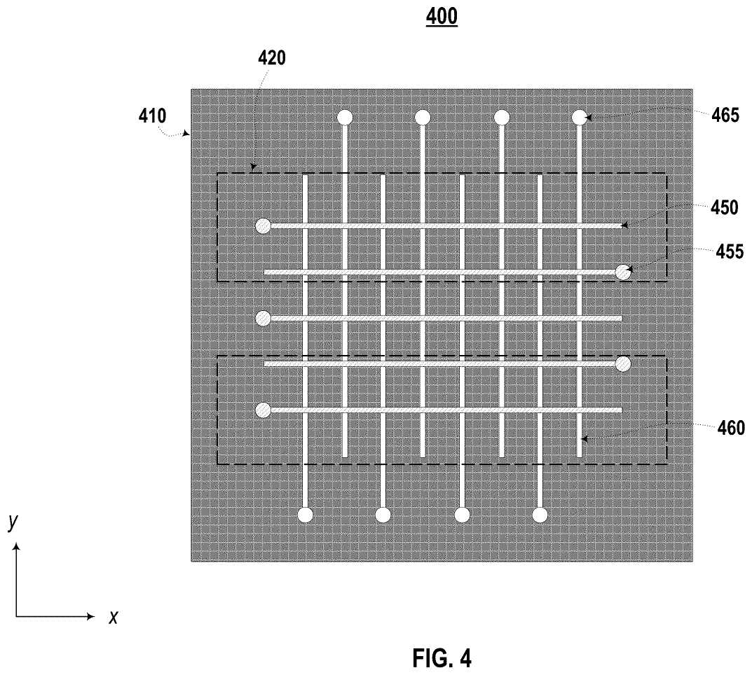

FIG. 4 illustrates a schematic layout diagram of a portion of a memory bank 400, according to some implementations of the present disclosure. As shown in FIG. 4, the word lines (WLs) 450 of the memory cell array 410 can extend in parallel along a first lateral direction (i.e., x-direction, referred to as the WL direction), while the bit lines (BLs) 460 of the memory cell array 410 can extend in parallel along a second lateral direction (i.e., y-direction, referred to as the BL direction) perpendicular to the first lateral direction. The word lines 450 and bit lines 460 may be formed in different lateral planes for ease of routing.

In some implementations, WL interconnection structures 455 can be located at both sides of each memory array 410 along the WL direction (the x-direction). The WLs 450 can be interconnected to the WL interconnection structures 455 in a staggered manner at both sides of each memory array 410 along the WL direction (the x-direction). For example, a first group of WL interconnection structures 455 located at a first side (e.g., left side in FIG. 4) of the memory array 410 can be connected to the odd numbers of WLs 450, and a second group of WL interconnection structures 455 located at a second side (e.g., right side in FIG. 4) of the memory array 410 can be connected to the even numbers of WLs 450.

In some implementations, BL interconnection structures 465 are located at both sides of each memory array 410 along the BL direction (the y-direction). The BLs 460 can be interconnected to the BL interconnection structures 465 in a staggered manner at both sides of each memory array 410 along the BL direction (the y-direction). For example, a first group of BL interconnection structures 465 located at a first side (e.g., lower side in FIG. 4) of the memory array 410 can be connected to the odd numbers of BLs 460, and a second group of BL interconnection structures 465 located at a second side (e.g., upper side in FIG. 4) of the memory array 410 can be connected to the even numbers of BLs 460. In some implementations, the BL interconnection structures 465 can be connected to the SA circuits 420. It is noted that, the memory cell array 410, the WLs 450, the BLs 460, the WL interconnection structures 455, the BL interconnection structures 465, and the SA circuits 420 can be formed on different lateral planes;

FIG. 4 merely shows top view of the portion of a memory bank 400.

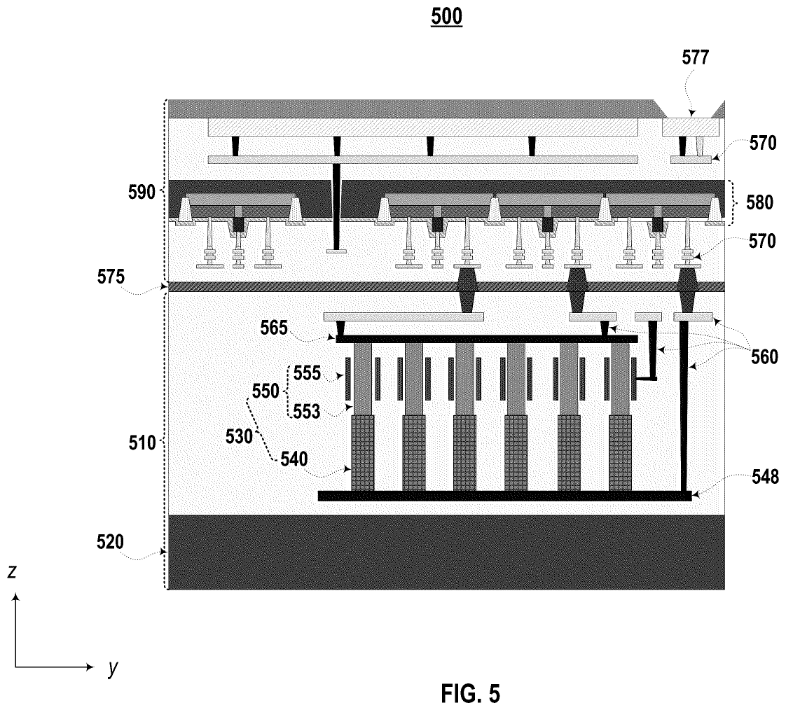

FIG. 5 illustrates a schematic side cross-sectional view of a portion of a memory bank 500 in the y-z plane, according to some implementations of the present disclosure. In some implementations, memory bank 500 can include a peripheral circuit structure 590 stacked on a memory array structure 510 in a vertical direction (the z-direction).

The memory array structure 510 can include a plurality of arrays of memory cells 530 on a substrate 520. Each memory cell 530 includes a vertical transistor 550 and a storage unit 540. In some implementations, the vertical transistor 550 can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc. Each vertical transistor 550 includes a semiconductor layer 553 and a gate electrode 555 at one or more lateral sides of semiconductor layer 553.

In some implementations, gate electrodes 555 of a row of vertical transistors 550 along the first lateral direction (the x-direction) can be connected with each other to form a word line extending along the first lateral direction (the x-direction). Gate electrode 555 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 555 may include doped polysilicon, i.e., gate poly. In some implementations, gate electrode 555 includes multiple conductive layers, such as a W layer over a TiN layer. In some implementations, a gate dielectric layer can be located between the semiconductor layer 553 and the gate electrode 555. The gate dielectric layer can include any suitable dielectric materials, such as silicon oxide, silicon nitride, silicon oxynitride, or high-k dielectrics.

In some implementations, bit lines 565 are in contact with ends (e.g., upper ends in FIG. 5) of semiconductor layer 553 and extend along the second lateral direction (the y-direction). In some implementations, bit lines 565 can include any suitable conductive materials, such as polysilicon, metals (e.g., W, Cu, Al, etc.), metal compounds (e.g., TiN, TaN, etc.), or silicides. In some implementations, bit lines 565 can include multiple conductive layers, such as a W layer over a TiN layer.

In some implementations, each memory cell 530 can further include a storage unit 540 coupled with the vertical transistor 550. The storage unit 540 can include any devices that can store binary data (e.g., 0 and 1), including but not limited to, capacitors for DRAM cells, and PCM elements for PCM cells. In some implementations, each vertical transistor 550 controls the selection and/or the state switch of the respective storage unit 540 coupled to the vertical transistor 550. In some implementations, the storage unit 540 includes a capacitor. It is understood that the capacitor may include any suitable structure and configuration, such as a planar capacitor, a stack capacitor, a multi-fins capacitor, a cylinder capacitor, a trench capacitor, or a substrate-plate capacitor. In some implementations, the capacitors may be coupled to a common electrode 548.

In some implementations, the memory array structure 510 can include array interconnection structures 560. For example, the array interconnection structures can include array contact structures, such as WL contacts, BL contacts, capacitor electrode contacts, etc. In some implementations, the array interconnection structures 560 can further include one or more first interconnection layers connecting with the array contact structures. In some implementations, the array interconnection structures 560 can further include array bonding pads. In some implementations, the array interconnection structures 560 can include any suitable conductive materials, such as polysilicon, metals (e.g., W, Cu, Al, etc.), metal compounds (e.g., TiN, TaN, etc.), or silicides.

In some implementations, the peripheral circuit structure 590 can be on the memory array structure 510 in the vertical direction. The peripheral circuit structure 590 can include various types of peripheral circuits formed using CMOS technologies. In some implementations, the peripheral circuit structure 590 can include WLD circuits 330 and SA circuits 320 that, including transistors 580. The peripheral circuit structure 590 can further include peripheral interconnection structures 570 coupled with the transistors 580. The peripheral interconnection structures 570 can include any suitable conductive structures, such as various conductive vias, conductive lines, conductive plates, etc., as transistor contacts, peripheral bonding pads, external connecting pads 577, and one or more second interconnection layers. In some implementations, the array interconnection structures 560 can further include array bonding pads. In some implementations, the peripheral interconnection structures 570 can include any suitable conductive materials, such as polysilicon, metals (e.g., W, Cu, Al, etc.), metal compounds (e.g., TiN, TaN, etc.), or silicides.

In some implementations, the peripheral circuit structure 590 can be bonded to the memory array structure 510 at bonding interface 575, such that the array bonding pads are coupled with the peripheral bonding pads. As such, the transistors 580 can be coupled to the arrays of memory cells 530 through the peripheral interconnection structures 570, the array interconnection structures 560, the bit lines 565, the word lines 555, and any other suitable metal wirings. It is noted that the one or more peripheral circuits can include any suitable circuits for facilitating operations of the arrays of memory cells 530 by applying and sensing voltage signals and/or current signals through word lines 555 and bit lines 565 to and from each vertical transistor 550.

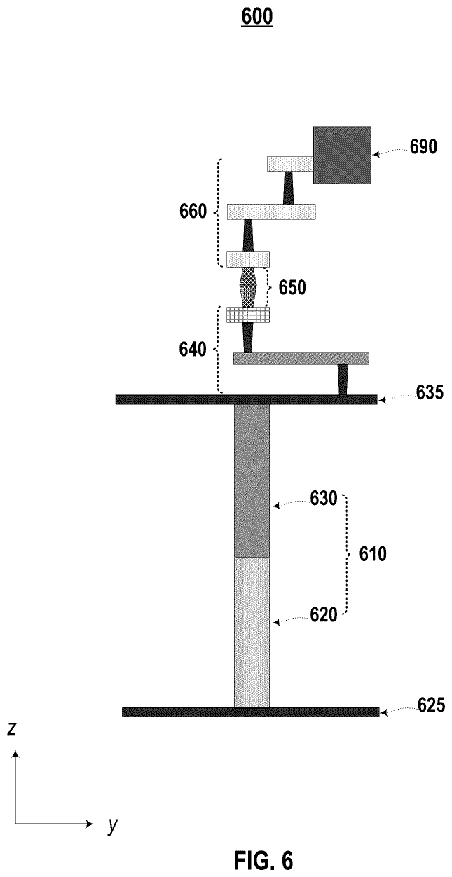

FIG. 6 illustrates a schematic side cross-sectional view of a portion of a memory bank 600 in the y-z plane, according to some implementations of the present disclosure. In some implementations, memory bank 600 can include a plurality of arrays of memory cells 610 each including a vertical transistor 630 and a storage unit 620. In some implementations, the vertical transistor 630 can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc. It is noted that, FIG. 6 shows one vertical transistor 630 for simplicity.

In some implementations, the memory cell 610 can further include a storage unit 620 coupled with the vertical transistor 630. The storage unit 620 can include any devices that can store binary data (e.g., 0 and 1), including but not limited to, capacitors for DRAM cells, and PCM elements for PCM cells. In some implementations, the vertical transistor 630 controls the selection and/or the state switch of the storage unit 620 coupled to the vertical transistor 630. In some implementations, the storage unit 620 is a capacitor. It is understood that the capacitor may include any suitable structure and configuration, such as a planar capacitor, a stack capacitor, a multi-fins capacitor, a cylinder capacitor, a trench capacitor, or a substrate-plate capacitor. It is noted that, FIG. 6 shows one storage unit 620 for simplicity.

In some implementations, bit lines 635 are in contact with the vertical transistors 630 and extend along the second lateral direction (the y-direction). In some implementations, storage unit lines 625 are in contact with the storage units 620. It is noted that, FIG. 6 shows one bit line 635 and one storage unit line 625 for simplicity.

In some implementations, the memory bank 600 can further include BL interconnection structures 640 connected with bit lines 635. In some implementations, the BL interconnection structures 640 can include one or more conductive layers and via contact structures. In some implementations, the BL interconnection structures 640 can include any suitable conductive materials, such as polysilicon, metals (e.g., W, Cu, Al, etc.), metal compounds (e.g., TiN, TaN, etc.), or silicides. It is noted that, FIG. 6 shows two conductive layers of the BL interconnection structures 640 as one example.

In some implementations, the memory bank 600 can further include SA circuits 690, and SA circuit interconnection structures 660 coupled with the SA circuits 690. The SA circuit interconnection structures 660 include one or more conductive layers and via contact structures. In some implementations, the SA circuit interconnection structures 660 can include any suitable conductive materials, such as polysilicon, metals (e.g., W, Cu, Al, etc.), metal compounds (e.g., TiN, TaN, etc.), or silicides. It is noted that, FIG. 6 shows three conductive layers of the bit the SA circuit interconnection structures 660 as one example.

In some implementations, the SA circuit interconnection structures 660 is coupled with the BL interconnection structures 640 through bonding pads 650. As such, each SA circuit 690 is electrically coupled to two BLs 635, through the SA circuit interconnection structures 660, the bonding pads 650, and the BL interconnection structures 640, to realize the function of amplifying the voltages on the two BLs 635.

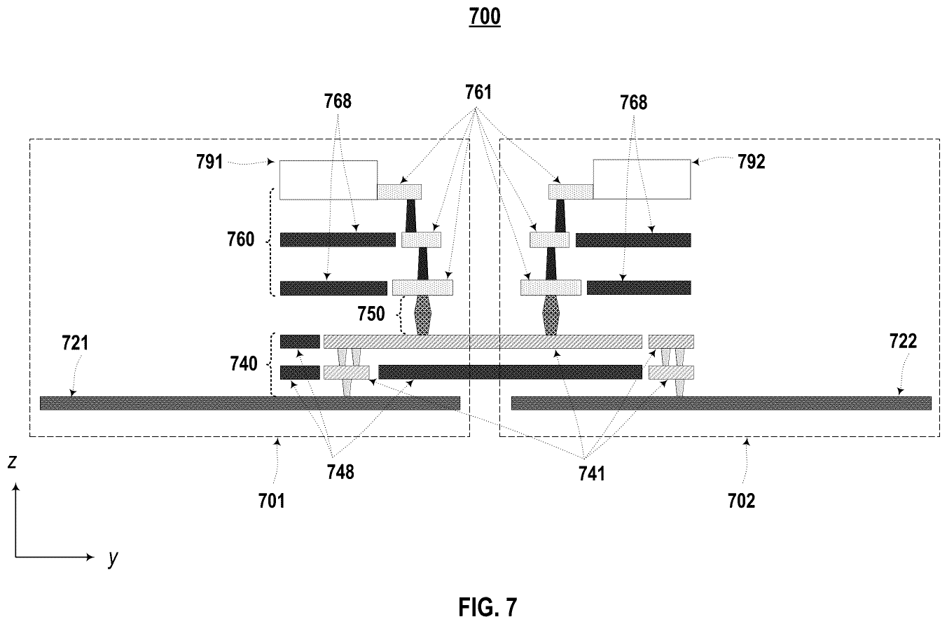

FIG. 7 illustrates a schematic side cross-sectional view of a portion of a memory bank 700 in the y-z plane, according to some implementations of the present disclosure. In some implementations, memory bank 700 can include two adjacent memory cell arrays 701 and 702. It is noted that, the memory cells including the vertical transistors and the storage units are omitted in FIG. 7 for simplicity. As shown in FIG. 7, the first memory cell array 701 can include first bit lines 721 and first SA circuit 791, and the second memory cell array 702 can include second bit lines 722 and second SA circuit 792.

In some implementations, the memory bank 700 can further include one or more first conductive layers 740 on the memory array side. It is noted that, FIG. 7 shows two first conductive layers 740 as one example. In some implementations, the one or more first conductive layers 740 can include first interconnection structures 741 connected with the bit lines 721 and 722 of the memory cell arrays 701 and 702. For example, the first interconnection structures 741 can be part of the BL interconnection structures 640 described in connection with FIG. 6. In some implementations, the first interconnection structures 741 can be connected between the first bit lines 721 of the first memory cell array 701 and the second first bit lines 722 of the second memory cell array 702. In some implementations, the one or more first conductive layers 740 can further include second interconnection structures 748 that are disconnected with the bit lines 721 and 722 of the memory cell arrays 701 and 702. In some implementations, the second interconnection structures 748 can be connected with each other by any suitable contacts to a common electrical node (not shown) to form a metal shielding structure. The formed metal shielding structure including the second interconnection structures 748 can effectively increase the total coupling capacitance of the bit lines 721 and 722, thereby optimizing the sense margin to ensure reliable data read operations of the formed memory device.

Similarly, the memory bank 700 can further include one or more second conductive layers 760 on the periphery circuit side. It is noted that, FIG. 7 shows three second conductive layers 760 as one example. In some implementations, the one or more second conductive layers 760 can include third interconnection structures 761 connected with the SA circuits 791 and 792, and coupled with the first interconnection structures 741 via bonding pads 750. For example, the third interconnection structures 761 can be part of the SA circuit interconnection structures 660 described in connection with FIG. 6. As such, the first and second SA circuits 791 and 792 can be coupled with the first bit lines 721 and second bit lines 722 through the third interconnection structures 761, the bonding pads 750, and the first interconnection structures 741. In some implementations, the one or more second conductive layers 760 can further include fourth interconnection structures 768 that are disconnected with the SA circuits 791/792 and the first interconnection structures 741. In some implementations, the fourth interconnection structures 768 can be connected with each other by any suitable contacts to a common electrical node (not shown) to form a metal shielding structure. The formed metal shielding structure including the fourth interconnection structures 768 can further increase the total coupling capacitance of the bit lines 721 and 722, thereby optimizing the sense margin to ensure reliable data read operations of the formed memory device.

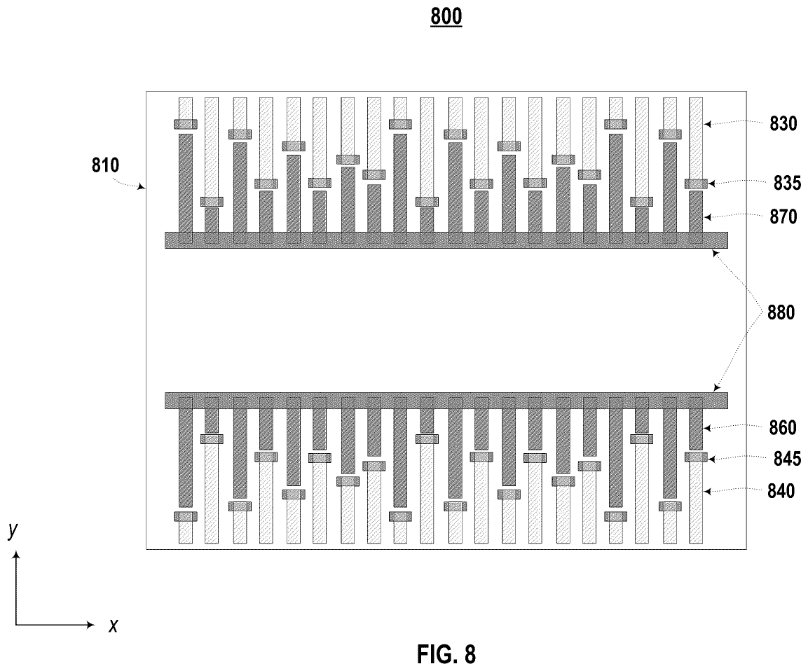

FIG. 8 illustrates a schematic top view of a portion of a memory bank 800 in the x-y plane, according to some implementations of the present disclosure. In some implementations, FIG. 8 shows one conductive layer of memory bank 800, such as one first conductive layer 740 or one second conductive layer 760 described above in connection with FIG. 7.

It is note that, although not shown in FIG. 8, the memory cell array 810 can include a plurality of bit lines extending in parallel along the second lateral direction (the y-direction). As shown in FIG. 8, a plurality of bit line contact structures 835, 845 can be located on opposite sides (e.g., upper side and lower side in FIG. 8) of the memory cell array 810 to be in contact with corresponding bit line, respectively. For example, first bit line contact structures 835 can be located at a first side of the memory cell array 810, and in contact with odd bit lines of the memory cell array 810. Second bit line contact structures 845 can be located at a second side of the memory cell array 810 opposite to the first side, and in contact with even bit lines of the memory cell array 810.

In some implementations, the first bit line contact structures 835 can be connected to first conductive lines 830, respectively. The first conductive lines 830 can be arranged along the first lateral direction (the x-direction). Each first conductive line 830 extends along the second lateral direction (the y-direction), and is coupled with one of the odd bit lines through a corresponding bit line contact structure 835. In some implementations, adjacent first conductive lines 830 have different first lengths along the second lateral direction, as shown in FIG. 8. In some implementations, aligned with the first conductive lines 830 along the second lateral direction, a plurality of second conductive lines 870 are arranged along the first lateral direction, and connected to a common conductive line 880 extending along the first lateral direction. Each second conductive line 870 extends along the second lateral direction, and is aligned with a corresponding one of the first conductive lines 830. In some implementations, adjacent second conductive lines 870 have different second lengths along the second lateral direction. In some implementations, the total length of each pair of first conductive line 830 and second conductive line 870 aligned along the second lateral direction can be equal, as shown in FIG. 8.

Similarly, the second bit line contact structures 845 can be connected to third conductive lines 840, respectively. The third conductive lines 840 can be arranged along the first lateral direction (the x-direction). Each third conductive line 840 extends along the second lateral direction (the y-direction), and is coupled with one of the even bit lines through a corresponding bit line contact structure 845. In some implementations, adjacent third conductive lines 840 have different first lengths along the second lateral direction, as shown in FIG. 8. In some implementations, aligned with the third conductive lines 840 along the second lateral direction, a plurality of fourth conductive lines 860 are arranged along the first lateral direction, and connected to a common conductive line 880 extending along the first lateral direction. Each fourth conductive line 860 extends along the second lateral direction, and is aligned with a corresponding one of the third conductive lines 840. In some implementations, adjacent fourth conductive lines 860 have different second lengths along the second lateral direction. In some implementations, the total length of each pair of third conductive line 840 and fourth conductive line 860 aligned along the second lateral direction can be equal, as shown in FIG. 8.

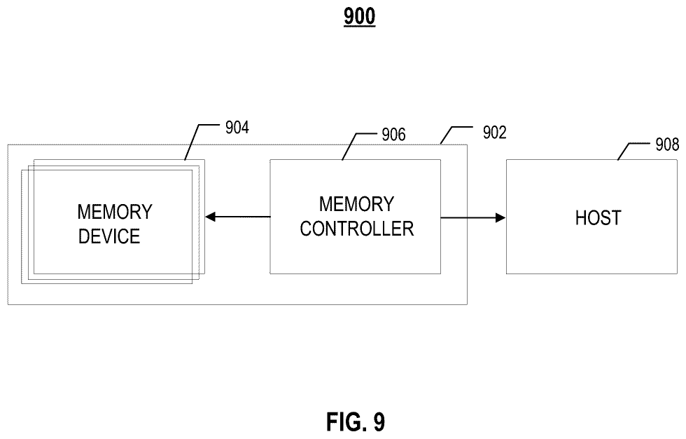

FIG. 9 illustrates a block diagram of a system 900 having a memory device, according to some implementations of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, system 900 can include a host 908 and a memory system 902 having one or more memory devices 904 and a memory controller 906. Host 908 can be a processor of an electronic device, such as a central processing unit (CPU), or a system-on-chip (SoC), such as an application processor (AP). Host 908 can be configured to send or receive the data to or from memory devices 904. Memory device 904 can be any memory devices disclosed herein, such as memory device 100. In some implementations, memory device 904 includes one or more memory banks described above in connection with FIGS. 2-8.

Memory controller 906 is coupled to memory device 904 and host 908 and is configured to control memory device 904, according to some implementations. Memory controller 906 can manage the data stored in memory device 904 and communicate with host 908. Memory controller 906 can be configured to control operations of memory device 904, such as read, write, and refresh operations. Memory controller 906 can also be configured to manage various functions with respect to the data stored or to be stored in memory device 904 including, but not limited to refresh and timing control, command/request translation, buffer and schedule, and power management. In some implementations, memory controller 906 is further configured to determine the maximum memory capacity that the computer system can use, the number of memory banks, memory type and speed, memory particle data depth and data width, and other important parameters. Any other suitable functions may be performed by memory controller 906 as well. Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

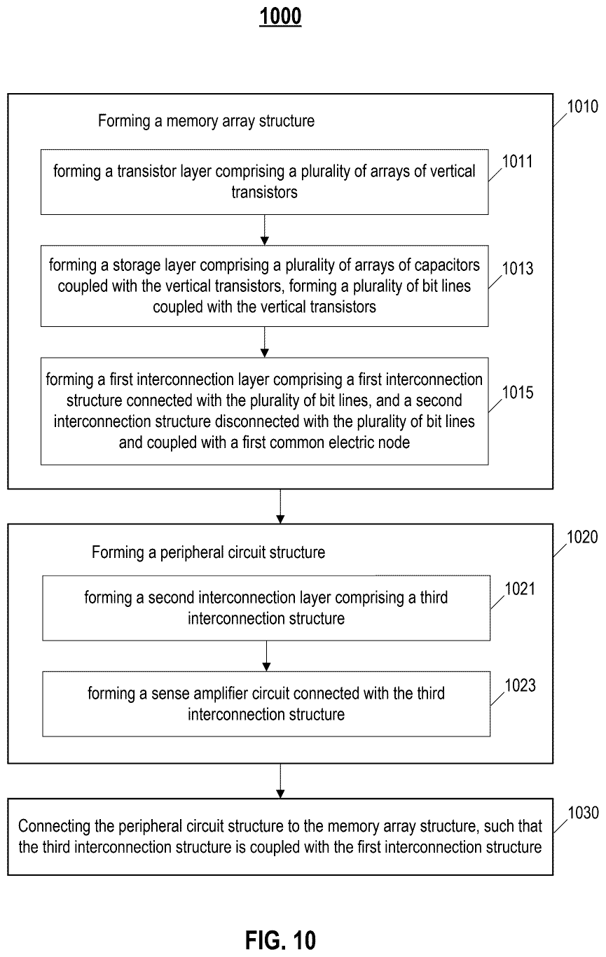

FIG. 10 illustrates a flowchart of a fabricating method 1000 for forming a semiconductor device, according to some implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1010, in which a memory array structure can be formed. In some implementations, operation 1010 of forming the memory array structure comprises the following steps: Step 1011: forming a transistor layer comprising a plurality of arrays of vertical transistors; Step 1013: forming a storage layer comprising a plurality of arrays of capacitors coupled with the vertical transistors, forming a plurality of bit lines coupled with the vertical transistors, and Step 1015: forming a first interconnection layer comprising a first interconnection structure connected with the plurality of bit lines, and a second interconnection structure disconnected with the plurality of bit lines and coupled with a first common electric node.

In some implementations, step 1015 of forming the first interconnection layer comprises connecting the first interconnection structure between bit lines of adjacent arrays of vertical transistors. In some implementations, step 1015 of forming the first interconnection layer further comprises forming a plurality of first conductive lines arranged along a first lateral direction. Each first conductive line extends along a second lateral direction and is coupled with a corresponding one of the bit lines through a bit line contact structure. In some implementations, forming the plurality of first conductive lines comprises forming adjacent first conductive lines having different first lengths along the second lateral direction. In some implementations, step 1015 of forming the first interconnection layer comprises forming at least two layers of conductive lines, wherein the first interconnection structure and the second interconnection structure are portions of the at least two layers of conductive lines.

In some implementations, step 1015 of forming the second interconnection structure comprises forming a plurality of second conductive lines arranged along the first lateral direction and connected to a common conductive line extending along the first lateral direction. Each second conductive line extends along the second lateral direction and is aligned with a corresponding one of the first conductive lines. In some implementations, forming the plurality of second conductive lines comprises forming adjacent second conductive lines having different second lengths along the second lateral direction. In some implementations, step 1015 of forming the second interconnection layer comprises forming at least two layers of conductive lines, wherein the third interconnection structure and the fourth interconnection structure are portions of the at least two layers of conductive lines.

In some implementations, operation 1010 of forming the memory array structure further comprises forming first bit line contact structures located at a first side of a corresponding array of vertical transistors, and in contact with odd bit lines of the corresponding array of vertical transistors. In some implementations, operation 1010 of forming the memory array structure further comprises forming second bit line contact structures located at a second side of the corresponding array of vertical transistors opposite to the first side, and in contact with even bit lines of the corresponding array of vertical transistors.

As shown in FIG. 10, method 1000 can then proceed to operation 1020, in which a peripheral circuit structure can be formed. In some implementations, operation 1020 of forming the peripheral circuit structure can include the following steps: Step 1021: forming a second interconnection layer comprising a third interconnection structure, and Step 1023: forming a sense amplifier circuit connected with the third interconnection structure.

In some implementations, step 1021 of forming the second interconnection layer further comprises forming a fourth interconnection structure disconnected with the sense amplifier circuit and the first interconnection structure, and connected to a second common electrical node. In some implementations, step 1021 of forming the second interconnection layer further comprises connecting the peripheral circuit structure with the memory array structure comprises connecting the first common electric node to the second common electrical node.

As shown in FIG. 10, method 1000 can then proceed to operation 1030, in which the peripheral circuit structure can be connected with the memory array structure, such that the third interconnection structure is coupled with the first interconnection structure. In some implementations, operation 1030 can include bonding the peripheral circuit structure to the memory array structure by using any suitable bonding techniques, such as a hybrid bonding process.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor device, comprising:
a memory array structure comprising:
a transistor layer comprising a plurality of arrays of vertical transistors,
a storage layer comprising a plurality of arrays of capacitors coupled with the vertical transistors,
a plurality of bit lines coupled with the vertical transistors, and
a first interconnection layer comprising a first interconnection structure connected with the plurality of bit lines, and a second interconnection structure disconnected with the plurality of bit lines and connected to a common electrical node; and
a peripheral circuit structure connected with the memory array structure, and comprising:
a second interconnection layer comprising a third interconnection structure connected with the first interconnection structure, and
a sense amplifier circuit connected with the third interconnection structure.

2. The semiconductor device of claim 1, wherein the second interconnection layer further comprises:
a fourth interconnection structure disconnected with the sense amplifier circuit and the first interconnection structure, and connected to the common electrical node.

3. The semiconductor device of claim 1, wherein the first interconnection structure is connected between bit lines of adjacent arrays of vertical transistors.

4. The semiconductor device of claim 1, wherein the first interconnection structure comprises:
a plurality of first conductive lines arranged along a first lateral direction, each first conductive line extends along a second lateral direction and is coupled with a corresponding one of the bit lines through a bit line contact structure.

5. The semiconductor device of claim 4, wherein adjacent first conductive lines have different first lengths along the second lateral direction.

6. The semiconductor device of claim 5, wherein the second interconnection structure comprises:
a plurality of second conductive lines arranged along the first lateral direction, and connected to a common conductive line extending along the first lateral direction,
wherein each second conductive line extends along the second lateral direction and is aligned with a corresponding one of the first conductive lines.

7. The semiconductor device of claim 6, wherein adjacent second conductive lines have different second lengths along the second lateral direction.

8. The semiconductor device of claim 1, wherein:
the first interconnection layer comprises at least two layers of conductive lines; and
the first interconnection structure and the second interconnection structure are portions of the at least two layers of conductive lines.

9. The semiconductor device of claim 2, wherein:
the second interconnection layer comprises at least two layers of conductive lines; and
the third interconnection structure and the fourth interconnection structure are portions of the at least two layers of conductive lines.

10. The semiconductor device of claim 1, wherein the memory array structure further comprises:
first bit line contact structures located at a first side of a corresponding array of vertical transistors, and in contact with odd bit lines of the corresponding array of vertical transistors; and
second bit line contact structures located at a second side of the corresponding array of vertical transistors opposite to the first side, and in contact with even bit lines of the corresponding array of vertical transistors.

11. A semiconductor device, comprising:
vertical transistors;
bit lines coupled with the vertical transistors;
a first interconnection structure comprising:
first conductive lines arranged along a first lateral direction, each first conductive line extending along a second lateral direction and being connected with a corresponding one of the bit lines, and
second conductive lines arranged along a first lateral direction, each second conductive line extending along the second lateral direction and being connected to a common electrical node and disconnected with the bit lines; and
a sense amplifier circuit connected with the bit lines through the first conductive lines.

12. The semiconductor device of claim 11, further comprising a second interconnection structure comprising:
third conductive lines connected between the first conductive lines and the sense amplifier circuit; and
fourth conductive lines connected to the common electrical node, and disconnected with the sense amplifier circuit and the first interconnection structure.

13. The semiconductor device of claim 11, wherein the first interconnection structure is connected between bit lines of adjacent arrays of vertical transistors.

14. The semiconductor device of claim 11, wherein each first conductive line is aligned with a corresponding one of the second conductive lines along the second lateral direction.

15. The semiconductor device of claim 14, wherein adjacent first conductive lines have different first lengths along the second lateral direction.

16. The semiconductor device of claim 15, wherein the second conductive lines are connected to a common conductive line extending along the first lateral direction.

17. The semiconductor device of claim 16, wherein adjacent second conductive lines have different second lengths along the second lateral direction.

18. The semiconductor device of claim 11, wherein the first conductive lines and the second conducive lines are distributed in at least two conductive wiring layers along a vertical direction.

19. The semiconductor device of claim 12, wherein the third conductive lines and the fourth conducive lines are distributed in at least two conductive wiring layers along a vertical direction.

20. The semiconductor device of claim 11, further comprising:
first bit line contact structures located at a first side of a corresponding array of vertical transistors, and in contact with odd bit lines of the corresponding array of vertical transistors; and
second bit line contact structures located at a second side of the corresponding array of vertical transistors opposite to the first side, and in contact with even bit lines of the corresponding array of vertical transistors.
